(19) United States
(12) Patent Application Publication
(10) Pub. No.: US 2014/0000519 A1
(43) Pub. Date: Jan. 2, 2014

(54) SUBSTRATE PROCESSING APPARATUS

(71) Applicant: JUSUNG ENGINEERING CO., LTD., Gwangju-si (KR)

(72) Inventors: Ho Chul LEE, Seongnam-si (KR); Sun Hong CHOI, Pyeongtaek-si (KR); Seung Ho LEE, Yongin-si (KR); Ji Hun LEE, Busan (KR); Dong Kyu LEE, Seoul (KR); Tae Wan LEE, Yongin-si (KR)

(73) Assignee: JUSUNG ENGINEERING CO., LTD., Gwangju-si (KR)

(21) Appl. No.: 14/014,323

(22) Filed: Aug. 29, 2013

Related U.S. Application Data
(63) Continuation of application No. 12/550,391, filed on Aug. 30, 2009.

(30) Foreign Application Priority Data
Sep. 5, 2008 (KR) 10-2008-0087774
Sep. 5, 2008 (KR) 10-2008-0087775
Sep. 18, 2008 (KR) 10-2008-0091716
Aug. 21, 2009 (KR) 10-2009-0077726

(51) Int. Cl. C23C 16/46

(52) U.S. Cl. CPC C23C 16/46
USPC 118/712; 118/725

(57) ABSTRACT

A substrate processing apparatus includes a chamber having a reaction space therein, a substrate seating member disposed in the reaction space of the chamber to seat a substrate thereon, an induction heating unit to heat the substrate seating member, and at least one altitude adjusting unit to selectively adjust the altitude of the induction heating unit at the outside of the chamber according to a temperature adjusting region of the substrate seating member. Therefore, it is possible to constantly control a temperature of the substrate seating member by adjusting the distance length between the substrate seating member and the induction heating unit at the outside of the chamber.

### CROSS-REFERENCE TO RELATED APPLICATION

This application is a continuation of U.S. patent application Ser. No. 12/550,391, filed Aug. 30, 2009, which claims priority to Korean Patent Application Nos. 10-2008-87774 filed on Sep. 5, 2008, 10-2008-87775 filed on Sep. 5, 2008, 10-2008-91716 filed on Sep. 18, 2008 and 10-2009-77726 field on Aug. 21, 2009, and all the benefits accruing therefrom under 35 U.S.C. §119, the contents of which are incorporated by reference in their entirety.

### BACKGROUND

The present disclosure relates to a substrate processing apparatus, and more particularly, to a substrate processing apparatus capable of uniformly heating a substrate seating member within a vacuum chamber and reducing power consumption of an induction heating unit used to heat the substrate seating member.

In general, a semiconductor device, an organic device and a solar cell device are fabricated by depositing a plurality of thin films and etching them to obtain desired properties. A substrate processing apparatus performs a process of depositing and etching the thin films in a high temperature that is equal to or greater than approximately 300° C. At this point, a temperature of a substrate on which the thin films are deposited acts as a very important factor in the thin film deposition process. That is, in case the temperature of the substrate is not uniform, a deposition rate of the thin film may be declined. Furthermore, in case a deposition temperature is low or the temperature of the substrate is not maintained uniformly during the thin film deposition process, properties of the thin film may be changed or the quality of the thin film may be deteriorated.

Therefore, a conventional substrate processing apparatus heats the substrate by heating a substrate seating member where the substrate is seated within a vacuum chamber. Such a heating unit uses an electric heater integrated with the substrate seating member or an optical heater that heats the substrate seating member disposed in the chamber using radiant heat at the outside of the chamber.

Recently, the substrate seating member is heated to a high temperature that is equal to or greater than approximately 400° C. by employing a high-frequency induction heating unit disposed in the vacuum chamber. This is a scheme of heating the substrate seating member by making an induced current flowing through the substrate seating member using an induced magnetic field generated by the induction heating unit. Therefore, it is possible to heat only the substrate seating member to a target temperature unless the induction heating unit is heated to a high temperature.

In general, the induction heating unit is installed in a region adjacent to the substrate seating member. That is, the induction heating unit is disposed under the substrate seating member to heat the substrate seating member having a large area. However, since the induction heating unit is not heated to the high temperature as described above, in case the induction heating unit is disposed under the substrate seating member, the heat of the substrate seating member heated to the high temperature may be taken by the induction heating unit. Namely, the induction heating unit acts as a major cause of the heat loss of the substrate seating member. Moreover, further power is required to compensate the heat loss of the substrate seating member.

Another problem is that a temperature of a central region of the substrate seating member becomes higher than that of an edge region by the induction heating unit disposed under the substrate seating member. As a result, the uniformity of the thin film is deteriorated when the thin film is deposited.

### SUMMARY

The present disclosure provides a substrate processing apparatus capable of preventing the heat loss of a substrate seating member by disposing a separate heat insulating unit between the substrate seating member and an induction heating unit, and maximizing the efficiency of the substrate heating by reducing the power loss of the induction heating unit.

The present disclosure further provides a substrate processing apparatus capable of reducing the generation of particles or dust due to a heat insulator by disposing the heat insulator in a heat insulating unit to prevent the heat insulator from being exposed to a reaction space of a chamber, and thus extending a replacement time of the heat insulator.

The present disclosure still further provides a substrate processing apparatus capable of uniformly controlling a temperature of a substrate seating member by adjusting a distance between the substrate seating member and an induction heating unit at the outside of a chamber, and improving the efficiency of the equipment uptime.

In accordance with an exemplary embodiment, a substrate processing apparatus includes: a chamber having a reaction space therein; a substrate seating member disposed in the reaction space of the chamber to seat a substrate thereon; an induction heating unit to heat the substrate seating member; and at least one altitude adjusting unit to selectively adjust the altitude of the induction heating unit at the outside of the chamber according to a temperature adjusting region of the substrate seating member.

The altitude adjusting unit may penetrate the chamber and may be connected to the induction heating unit disposed under a susceptor.

The altitude adjusting unit may include a coil fixing support, an insulator wrapping a lower portion of the coil fixing support, a shaft penetrating the chamber towards a lower portion of the insulator, an upper support and a lower support installed at an outer side and an inner side of the chamber, respectively, wherein the shaft is disposed between the upper support and the lower support, a bellows to move the shaft towards a lower part of the lower support, and a distance controller to control the movement of the coil fixing support towards a lower part of the bellows.

The substrate processing apparatus may further include: a plurality of driving motors corresponding to the distance controller; and a sensor support, to which a sensing device is attached, disposed in a space between the bellows and the distance controller, wherein the sensing device uses one of a sensor and a gauge.

The insulator may include one of quartz and a ceramic material including AlO, AlN, BN or SiC.

The substrate processing apparatus may further include a heat insulating member disposed between the induction heating unit and the substrate seating member, wherein the heat insulating member may use one or more of opaque quartz, SiC and ceramic.

The substrate processing apparatus may further include a heat insulating member disposed between the induction heating unit and the substrate seating member, wherein the heat insulating member may include a heat insulator, a lower body disposed in the reaction space and collecting the heat insulator therein, and an upper cover covering the lower body, and the heat insulator may use one or more of a heat insulator of alumina series, a heat insulator of silica series and carbon felt.

The induction heating unit may be disposed within the chamber; a window member may be disposed over the induction heating unit; a heat insulating member may be disposed over the window member; and a plurality of supporting axles may be disposed between the window member and the heat insulating member.

The substrate processing apparatus may further include a heat insulating member disposed under the substrate seating member and collecting a heat insulator therein, the heat insulator using one or more of a heat insulator of alumina series, a heat insulator of silica series and carbon felt, wherein the induction heating unit may be disposed within the heat insulating member and the altitude adjusting unit may penetrate a part of the chamber to be connected to the heat insulating member.

The induction heating unit may include at least one induction coil disposed under a heat insulating member, and a power supplying source to provide high-frequency power to the induction coil, wherein the altitude adjusting unit is connected to the induction coil.

In accordance with another exemplary embodiment, a substrate processing apparatus includes: a chamber having a reaction space therein; a substrate seating member disposed in the chamber to seat a substrate thereon; an induction heating unit to heat the substrate seating member through the induction heating; a window member disposed over the induction heating unit; and at least one heat insulating member disposed between the induction heating unit and the window member.

The substrate processing apparatus may further include a plurality of supporting axles disposed between the window member and the heat insulating member.

The heat insulating member may block radiant heat and use one or more of opaque quartz, SiC and ceramic that do not affect the induction heating.

The heat insulating member may include a heat insulator, a lower body disposed in the reaction space and collecting the heat insulator therein and an upper cover covering the lower body, and the heat insulator may use one or more of a heat insulator of alumina series, a heat insulator of silica series and carbon felt.

The substrate processing apparatus may further include an altitude adjusting unit moving the induction heating unit up and down to control a distance between the induction heating unit and the substrate seating member.

In accordance with still another exemplary embodiment, a substrate processing apparatus includes: a chamber having a reaction space therein; a substrate seating member disposed in the chamber to seat a substrate thereon; a heat insulating member disposed under the substrate seating member and collecting a heat insulator therein; and an induction heating unit disposed in the heat insulating member to heat the substrate seating member through the induction heating.

The heat insulating member may include a lower body disposed in the reaction space and collecting the heat insulator therein and an upper cover covering the lower body, and the heat insulator may use one or more of a heat insulator of alumina series, a heat insulator of silica series and carbon felt.

### BRIEF DESCRIPTION OF THE DRAWINGS

Exemplary embodiments can be understood in more detail from the following description taken in conjunction with the accompanying drawings, in which:

FIG. 1 illustrates a cross-sectional view of a substrate processing apparatus in accordance with a first embodiment of the present invention;

FIG. 2 illustrates a conceptual perspective view of a heat insulating member and a window member in accordance with the first embodiment;

FIG. 3 illustrates a conceptual plan view of the heat insulating member in accordance with the first embodiment;

FIG. 4 illustrates a conceptual plan view of an induction heating unit in accordance with a modification of the first embodiment;

FIGS. 5 to 9 illustrate conceptual cross-sectional views for explaining a shape of a heat insulating member in accordance with a modification of the first embodiment;

FIG. 10 illustrates a cross-sectional view of a substrate processing apparatus in accordance with a second embodiment of the present invention;

FIG. 11 illustrates an exploded perspective view of a heat insulating member in accordance with the second embodiment;

FIG. 12 illustrates a plan view of the heat insulating member in accordance with the second embodiment;

FIG. 13 illustrates a plan view of a heat insulating member in accordance with a modification of the second embodiment;

FIGS. 14 to 16 illustrate conceptual cross-sectional views for explaining a shape of the heat insulating member in accordance with the modification of the second embodiment;

FIG. 17 illustrates a cross-sectional view of a substrate processing apparatus in accordance with a third embodiment of the present invention;

FIG. 18 illustrates a cross-sectional view of a substrate processing apparatus in accordance with a fourth embodiment of the present invention;

FIG. 19 illustrates a view of an altitude adjusting unit of an induction heating scheme in accordance with the fourth embodiment;

FIG. 20 illustrates a plan view of a substrate seating member in accordance with the fourth embodiment;

FIG. 21 illustrates an exploded perspective view of the altitude adjusting unit in accordance with the fourth embodiment;

FIG. 22 illustrates a cross-sectional view taken along a B-B′ line described in FIG. 21;

FIG. 23 illustrates a cross-sectional view of a heat generating unit and the substrate seating member in accordance with the fourth embodiment;

FIG. 24 illustrates a perspective view of a coil fixing device in accordance with the fourth embodiment; and

FIG. 25 illustrates a plane view of a heat generating unit and a substrate seating member in accordance with a modification of the fourth embodiment.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Furthermore, the same or like reference numerals represent the same or like constituent elements, although they appear in different embodiments or drawings of the present invention.

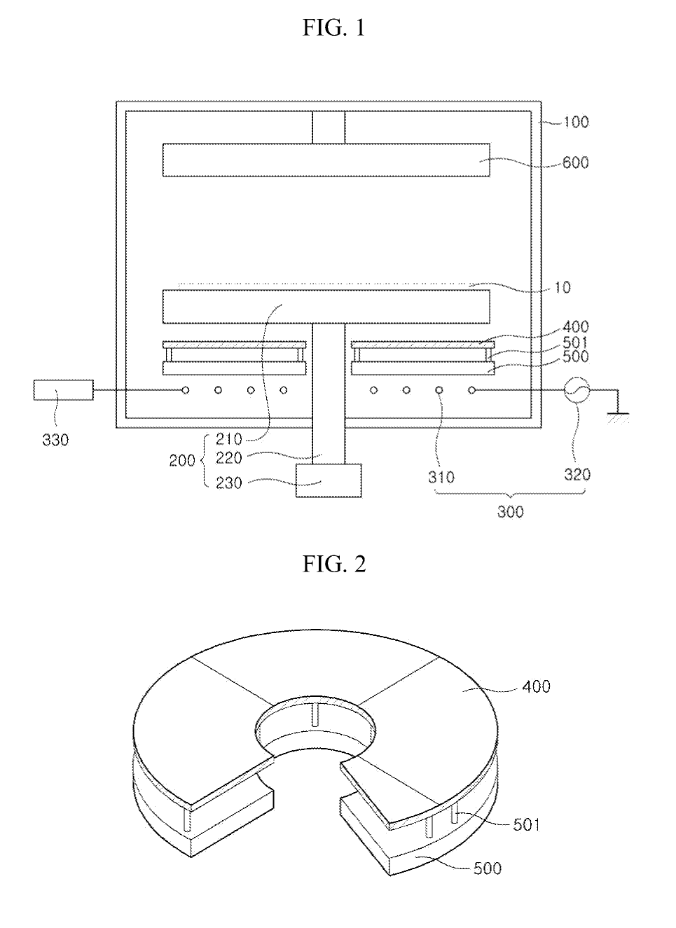

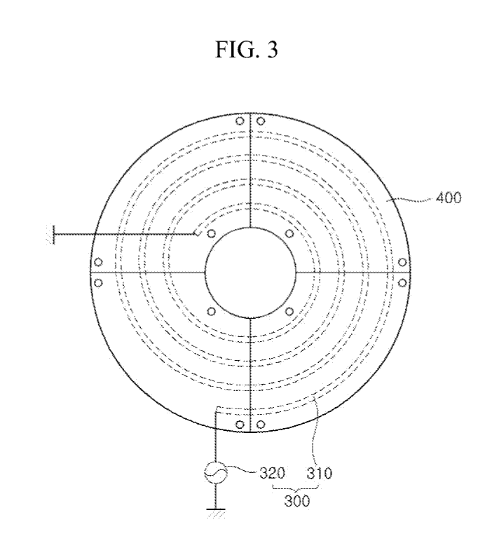

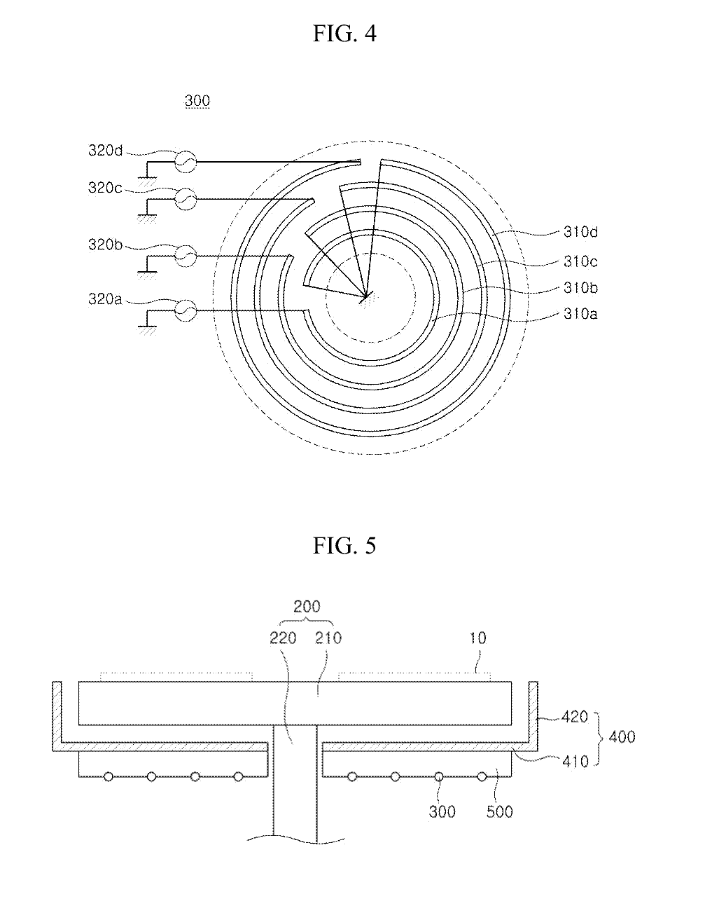

FIG. 1 illustrates a cross-sectional view of a substrate processing apparatus in accordance with a first embodiment of the present invention. FIG. 2 illustrates a conceptual perspective view of a heat insulating member and a window member in accordance with the first embodiment. FIG. 3 illustrates a conceptual plan view of the heat insulating member in accordance with the first embodiment. FIG. 4 illustrates a conceptual plan view of an induction heating unit in accordance with a modification of the first embodiment. FIGS. 5 to 9 illustrate conceptual cross-sectional views for explaining shapes of the heat insulating member in accordance with modifications of the first embodiment.

Referring to FIGS. 1 to 3, the substrate processing apparatus in accordance with the first embodiment includes a chamber 100 having an inner reaction space, a substrate seating member 200 seating a substrate 10 within the chamber 100, an induction heating unit 300 heating the substrate seating member 200 through high-frequency induction heating, and a heat insulating member 400 disposed between the substrate seating member 200 and the induction heating unit 300. As described in FIG. 1, the substrate processing apparatus further includes the window member 500 installed over the induction heating unit 300, and a gas injecting member 600 injecting a processing gas onto the substrate 10 that is heated. Although it is not shown, the substrate processing apparatus may further include a pressure adjusting unit adjusting a pressure within the chamber 100 and an exhaust unit exhausting the inside of the chamber 100.

The chamber 100 is formed in a tube shape having an inner space. Herein, the chamber 100 may be formed in a cylindrical shape or a polygonal tube shape. Although it is not shown, the chamber 100 may include a chamber body and a chamber lead that are combined to each other to be removable.

The substrate 10 is disposed in the reaction space of the chamber 100. Herein, the substrate seating member 200 is provided to seat the substrate 10 in the reaction space. In this embodiment, the substrate seating member 200 is heated in an electromagnetic field using an electromagnetic induction principle of a high-frequency current, thereby heating the substrate 10 on the substrate seating member 200 up to a processing temperature.

As shown in FIG. 1, the substrate seating member 200 includes a main disk 210 on which the substrate 10 is seated, a driving axle 220 connected to a center of the main disk 210 and a driving element 230 moving the main disk 210 through the driving axle 220.

The main disk 210 is formed in the same plate shape as that of the substrate 10. It is effective that the main disk 210 includes a seating region where at least one substrate is seated. The main disk 210 uses a material that is able to be heated to a temperature equal to or greater than approximately 300° C. by high-frequency induction heating, i.e., the electromagnetic induction of the high-frequency current. It is preferable that the main disk 210 is formed of a material that is able to be heated to the maximum 1400° C.

The driving axle 220 is connected to the main disk 210 in the reaction space and extended to the outside of the chamber 100. At this point, the driving axle 220 penetrates a soleplate of the chamber 100 and is connected to the driving element 230. Therefore, the soleplate of the chamber 100 may have a penetration groove. Although it is not shown, a sealing element such as a bellows may be provided to the circumference of the penetration groove, thereby sealing the inside of the chamber 100. Herein, the driving axle 220 is formed of a material having low thermal conductivity. This is because one end of the driving axle 220 is connected to the main disk 210 that is heated and thus, if the thermal conductivity of the driving axle 220 is high, the heat loss of the main disk 210 may be increased.

The driving element 230 provides an up and down force or a rotation force to the driving axle 220 to up or down, or rotate the main disk 210. The driving element 230 may use a stage including a plurality of motors.

Although it is not shown, the substrate seating member 200 may further include a plurality of lift pins to help loading and unloading of the substrate 10.

In this embodiment, the substrate processing apparatus includes the induction heating unit 300 disposed under the main disk 210 of the substrate seating member 200 to heat the main disk 210 through the high-frequency induction heating. As mentioned above, the induction heating unit 300 heats the main disk 210 using the electromagnetic induction principle of the high-frequency current.

The induction heating unit 300 includes an induction coil 310 through which the high-frequency current flows, a high-frequency power supplying source 320 to provide high-frequency power to the induction coil 310, and a cooling element 330 to cool the induction coil 310.

The induction coil 310 is arranged in a spiral shape as shown in FIG. 3. Thus, it is possible to generate a uniform high-frequency magnetic field to the substrate seating member 200. At this point, a surface temperature of the main disk 210 may be changed according to a distance length between the induction coil 310 and the substrate seating member 200, and/or an interval between turning coils. FIG. 3 shows that the interval between the tuning coils is constant. However, the present invention is not limited to this embodiment and the interval may be reduced as going from a central region to an edge region of the induction coil 310. As a result, it is possible to prevent the heat from being focused on a central region of the substrate seating member 200.

FIG. 1 illustrates that the induction coil 310 having the spiral shape is disposed on a plane that is parallel to a bottom surface of the main disk 210. That is, a distance length between the induction coil 310 and the main disk 210 is constantly maintained. However, the present invention is not limited to this embodiment and the distance length between the induction coil 310 and the substrate seating member 200 at the central region of the substrate seating member 200 may be greater than that at an edge region of the substrate seating member 200. Thus, it is possible to uniformly maintain the temperature distribution of a top surface of the substrate seating member 200. This is because an induced magnetic force provided to the substrate seating member 200 is changed according to an altitude of the induction coil 310.

The high-frequency power supplying source 320 provides the high-frequency power to the induction coil 310. At this point, the high-frequency power is in a power strength range of approximately 10 kW to approximately 400 kW and a frequency range of approximately 10 KHz to approximately 1 MHz. The high-frequency magnetic field generated by the induction coil 310 is changed according to the power strength and the frequency of the high-frequency power. As a result, the substrate seating member 200 may be heated to various temperatures.

It is effective that the high-frequency power supplying source 320 in this embodiment is disposed at the outside of the chamber 100 and electrically connected to the induction coil 310 through a separate wire.

The construction of the induction heating unit 300 is not limited to this embodiment and may be variously changed. In particular, the induction coil 310 may be arranged in various manners. That is, as illustrated in FIG. 4, the induction heating unit 300 may include plural induction coils 310a to 310d that are concentric and have circular ring shapes of different diameters, respectively. Moreover, the induction coils 310a to 310d may operate separately. For this purpose, as shown in FIG. 4, a plurality of high-frequency power supplying sources 320a to 320d respectively connected to the induction coils 310a to 310d may be further employed to independently supply the high-frequency power to the induction coils 310a to 310d. Therefore, it is possible to uniformly heat the substrate seating member 200 by changing the frequency and the power strength of the high-frequency power according to the needs. Furthermore, it is possible to divide the substrate seating member 200 into a plurality of regions and to dispose an induction coil under each of the regions, wherein the induction coils disposed under the plurality of regions independently operate. Through this, temperatures of the plurality of regions of the divided substrate seating member 200 may be separately adjusted from each other.

Herein, the induction coil 310 is disposed to be adjacent to a lower portion of the substrate seating member 200 that is heated to the high temperature by the high-frequency induction heating. Thus, the heat of the substrate seating member 200 may be transmitted to the induction coil 310. The induction coil 310 is formed of a metallic material having excellent conductivity such as copper. However, the metallic material such as the copper is easily deformed by the heat. Therefore, in this embodiment, the cooling element 330 for cooling the induction coil 310 is further disposed at the inside or the outside of the induction coil 310, wherein the cooling element 330 uses cooling fluid. That is, the cooling element 330 may cool the induction coil 310 by injecting the cooling fluid to the inner space of the induction coil 310. Moreover, although it is not shown, the cooling element 330 may further include a separate cover body wrapping the induction coil 310 and thus cool the induction coil 310 by injecting the cooling fluid into a space between the cover body and the induction coil 310.

Herein, although the induction coil 310 is cooled by the cooling element 330, the heat of the substrate seating member 200 is also taken by the cooling element 330. The heat of the substrate seating member 200 may be further transmitted to the soleplate of the chamber 100 through a space between turning induction coils. Therefore, power on which the heat loss is reflected should be supplied to heat the substrate seating member 200 up to a target temperature. As a result, the power consumption may be increased.

In this embodiment, the heat insulating member 400 is installed between the substrate seating member 200 and the induction heating unit 300 so as to prevent the heat loss of the substrate seating member 200. In addition, in this embodiment, as illustrated in FIGS. 1 to 3, the window member 500 is disposed between the heat insulating member 400 and the induction heating unit 300 to prevent the induction heating unit 300 from being contaminated by the processing gas supplied to the chamber 100.

In this embodiment, the heat insulating member 400 is disposed over the window member 500, i.e., underneath the substrate seating member 200. Therefore, the heat loss to a lower part of the substrate seating member 200 may be cut off and the power consumption of the induction heating unit 300 is reduced.

The window member 500 has a penetration hole in the center as shown in FIG. 2 and is formed in a plate shape similar to the substrate seating member 200. In this embodiment, the window member 500 is formed in a circular plate shape. The window member 500 is formed of a material penetrating an electromagnetic force. That is, the window member 500 uses a material that is not heated by the high-frequency induction. Therefore, the window member 500 may not be affected by a high-frequency induction heating phenomenon of the induction heating unit 300. Moreover, it is possible to minimize the deforming or blocking of the high-frequency magnetic field.

It is effective to form the window member 500 with a material that does not generate particles in the chamber 100 since the window member 500 is disposed in the reaction space of the chamber 100. It is effective to use quartz as the window member 500.

The window member 500 may has a diameter greater than the whole diameter of the turning induction coil 310 of the induction heating unit 300. This is because the window member 500 is disposed over the induction coil 310 of the induction heating unit 300 to prevent byproducts in the reaction space from being attached to the induction coil 310.

Then, the heat insulating member 400 is disposed over the window member 500.

The heat insulating member 400 is formed of a material having low thermal conductivity. The thermal conductivity may be less than approximately 10 W/mk. Through this, it is possible to reduce the heat loss of the substrate seating member 200 that is heated to the high temperature. It is preferable that the heat insulating member 400 uses a material capable of blocking radiant heat, i.e., an infrared ray, or having low transmissivity. Namely, it is possible to prevent the soleplate of the chamber 100 or the induction heating unit 300 from being heated by the radiant heat by blocking the radiant heat.

It is effective to form the heat insulating member 400 with a material that is not heated by the induction heating phenomenon of the induction heating unit 300. Preferably, the heat insulating member 400 is formed of a material that does not affect the high-frequency magnetic field. As a result, it is possible not to disturb the induction heating provided to the substrate seating member 200.

The heat insulating member 400 is formed of a material that does not generate particles in the chamber 100. That is, the heat insulating member 400 is disposed in the reaction space of the chamber 100. Therefore, the heat insulating member 400 reacts with the processing gas supplied into the chamber 100 and thus acts as a particle source.

In this embodiment, the heat insulating member 400 may use one or more of opaque quartz, SiC and ceramic.

The heat insulating member 400 is formed in a plate shape having a penetration hole at the center as shown in FIGS. 2 and 3. That is, the heat insulating member 400 may be formed in a circular plate shape similar to the substrate seating member 200.

As shown in drawings, the heat insulating member 400 may be formed with plural parts that are combined for the simplicity of fabrication. For instance, as shown in FIG. 3, the heat insulating member 400 is formed by combining 4 numbers of heat insulating bodies having a fan shape. The present invention is not limited to this embodiment. The number of the heat insulating bodies constructing the heat insulating member 400 may be smaller or greater than 4.

As illustrated in FIGS. 1 to 3, each insulating body of the heat insulating member 400 is attached to the window member 500 by a plurality of supporting axles 501. The heat insulating member 400 is separated from the window member 500 by the supporting axles 501. It is possible to enhance a heat insulating effect of the heat insulating member 400 by separating the heat insulating member 400 from the window member 500. Herein, it is effective that the plural supporting axles 501 use quartz of a stick shape. The supporting axles 501 may act as fixing means. According to the needs, fixing members may be further employed to fix the supporting axles 501, and the heat insulating member 400 and the window member 500.

As illustrated in FIG. 1, it is effective that a diameter of the heat insulating member 400 is similar to a diameter of a bottom side of the main disk 210 of the substrate seating member 200. It is preferable that the diameter of the heat insulating member 400 is greater than a maximum diameter of the induction coil 310 of the induction heating unit 300. Thus, it is possible to block the heat loss through the bottom side of the substrate seating member 200 by covering the whole bottom side of the substrate seating member 200.

The heat insulating member 400 is not limited to the shape described above and may be formed in various shapes. Various modifications of the substrate processing apparatus according to the changes of the heat insulating member 400 will be described with reference to FIGS. 5 to 9.

First of all, in the modification described in FIG. 5, the heat insulating member 400 includes a heat insulating body 410 formed in a plate shape corresponding to the bottom side of the substrate seating member 200, and a projected body 420 protruding upwards at an edge region of the heat insulating body 410 to correspond to a lateral wall of the substrate seating member 200. It is possible to prevent the heat loss through the lateral wall of the substrate seating member 200 by covering the lateral wall of the substrate seating member 200 with the projected body 420. The lateral wall of the substrate seating member 200 is arranged adjacent to an inner lateral wall of the chamber 100. Thus, the heat loss of the substrate seating member 200 may occur due to the inner lateral wall of the chamber 100. The heat loss may be prevented by disposing the projected body 420 having a heat insulating characteristic to correspond to the lateral wall of the substrate seating member 200 as shown in FIG. 5. In this modification, the heat insulating body 410 and the projected body 420 are formed in a single body. However, the present invention is not limited to this modification. That is, the heat insulating body 410 may be separated from the projected body 420.

In the modification illustrated in FIG. 5, a plurality of substrates may be seated on the substrate seating member 200. Moreover, the window member 500 may be attached to a bottom side of the heat insulating member 400. A groove may be formed at a bottom side of the window member 500 and thus the induction coil 310 of the induction heating unit 300 may come in and out of the groove. Through this, the contamination of the induction coil 310 may be prevented.

In the modification illustrated in FIG. 6, the heat insulating member 400 may include the heat insulating body 410 and an extended body 430 that is extended downwards at the edge region of the heat insulating body 410. The contamination of the induction coil 310 of the induction heating unit 300 may be prevented by disposing the induction heating unit 300 in an inner space of the extended body 430 and the heat insulating body 410. Thus, the window member 500 described in the above embodiments may be omitted in this modification. That is, the induction coil 310 is disposed under the heat insulating body 410 and thus thermally isolated from the substrate seating member 200 that is in the high temperature. Since the extended body 430 is disposed in a lateral direction of the induction coil 310, it is possible to block the inflow of reaction byproducts or an un-reacted gas in the lateral direction of the induction coil 310.

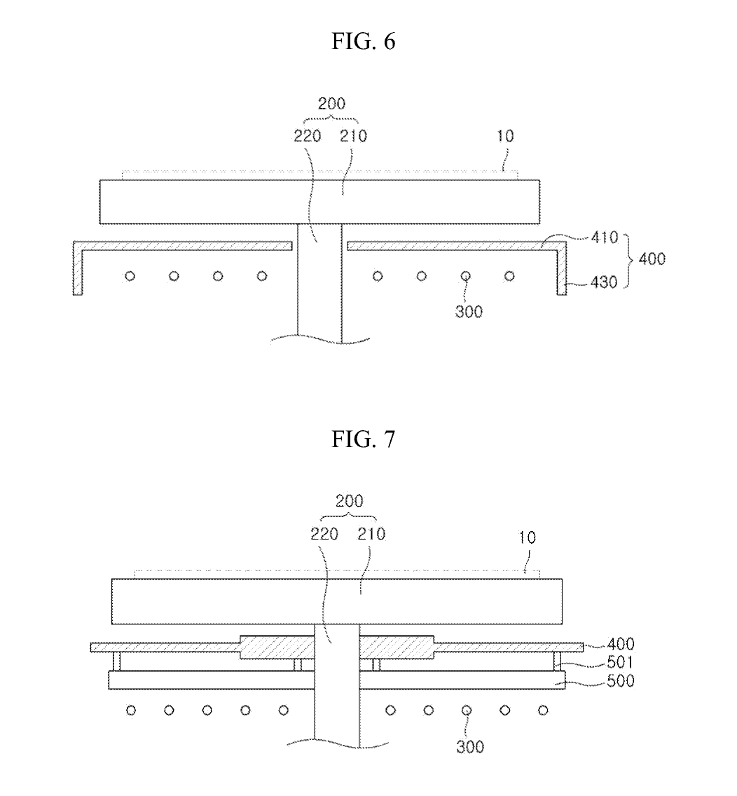

In the modification illustrated in FIG. 7, the heat insulating member 400 may be formed to have a thickness at its central region greater than a thickness at its edge region. This heat insulating member 400 may be used when the heat loss may occur much more at the central region of the substrate seating member 200. Namely, the heat insulating effect at the central region of the heat insulating member 400 may be enhanced by forming the heat insulating member 400 to have the thickness at the central region greater than that at the edge region.

In FIG. 7, the heat insulating member 400 and the window member 500 are fixed on the driving axle 220. Thus, when the substrate seating member 200 ascends or descends, the heat insulating member 400 and the window member 500 also go down and up simultaneously. Through this, the distance length between the substrate seating member 200 and the heat insulating member 400 may be maintained constantly. The present invention is not limited to this modification. The heat insulating member 400 and the window member 500 may be fixed on the soleplate of the chamber 100 through separate fixing means.

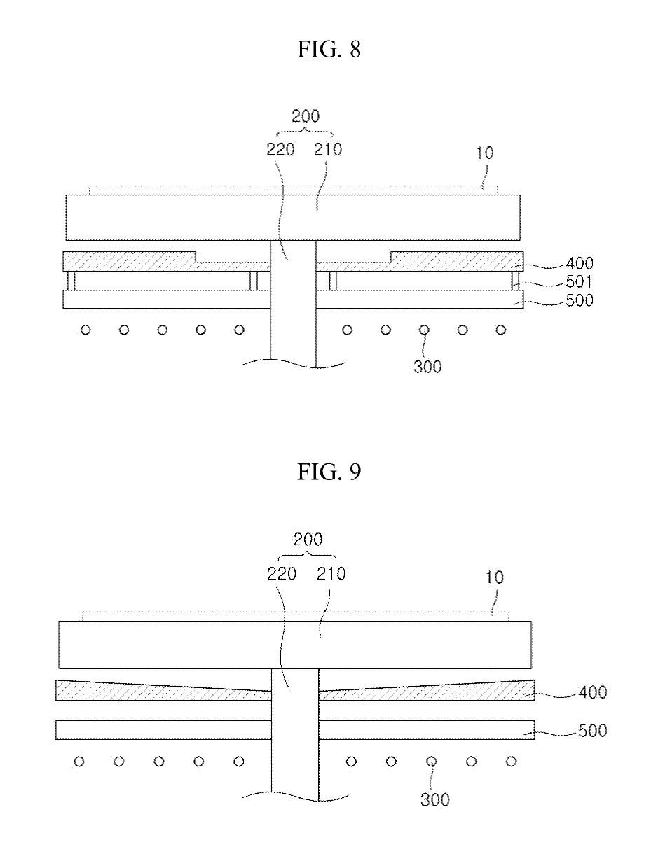

In the modification illustrated in FIG. 8, the heat insulating member 400 may be formed to have the thickness at its edge region greater than the thickness at its central region. This heat insulating member 400 may be used when the heat loss may occur much more at the edge region of the substrate seating member 200. Namely, the heat loss at the edge region of the substrate seating member 200 may be reduced by forming the heat insulating member 400 having the thickness at the edge region greater than that at the central region.

In the modification illustrated in FIG. 9, the heat insulating member 400 is formed to have a thickness that becomes greater as going from the central region to the edge region.

Without being limited to the above description, the substrate processing apparatus may further include a plurality of heat insulating members. The above description shows the heat insulating member 400 of a single layer. However, the present invention is not limited thereto and the heat insulation effect can be further enhanced by employing the heat insulating member 400 of plural layers.

Hereinafter, there will be explained experimental results according to a comparative example not using the heat insulating member 400, a first embodiment using opaque quartz as the heat insulating member 400 and a second embodiment using ceramic as the heat insulating member 400.

Table 1 describes results of measuring power provided to the induction heating unit 300 to raise a temperature of the main disk 210 of the substrate seating member 200 up to 800° C.

TABLE 1

| | Power | Heat insulating effect |
|---|---|---|
| Comparative example | 66 kW | 1 time |
| 1^{st} embodiment | 42 kW | 1.57 times |
| 2^{nd} embodiment | 38 kW | 1.74 times |

As shown in Table 1, in case of the comparative example not using the heat insulating member 400, the power of 66 kW was required to heat the main disk 210 of the substrate seating member 200 up to 800° C. However, in the first embodiment using the opaque quartz as the heat insulating member 400, the power of 42 kW was required. In the second embodiment using the ceramic as the heat insulating member 400, the power of 38 kW was required. That is, it is noted that the power consumption in case of using the heat insulating member 400 is lower than that in case of not using the heat insulating member 400. Therefore, it is possible to enhance the power efficiency by using the heat insulating member 400. This means that the substrate seating member 200 can be heated up to the target temperature by using much lower power.

As described above, the substrate seating member 200 is heated by the induction heating unit 300. The substrate 10 is also heated up to the high temperature by seating the substrate 10 on the heated substrate seating member 200.

A thin film is formed by injecting the processing gas through the gas injecting member 600 onto the heated substrate 10 in the chamber 100.

The description of the modifications shown in the above embodiments may be applied to other modifications. Hereinafter, other embodiments of the present invention will be described. The explanation overlapping with that of the first embodiment will be omitted below. Moreover, the description to be shown below can be applied to the first embodiment.

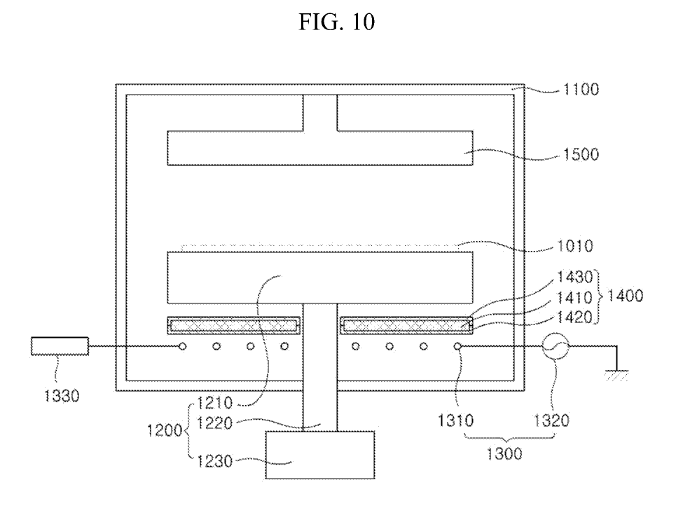

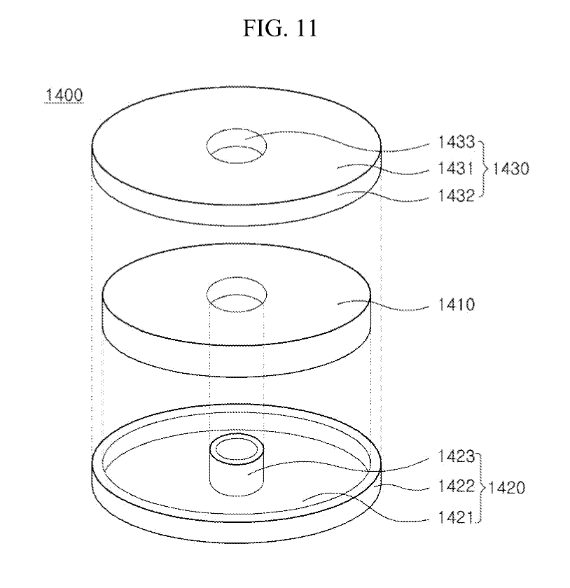

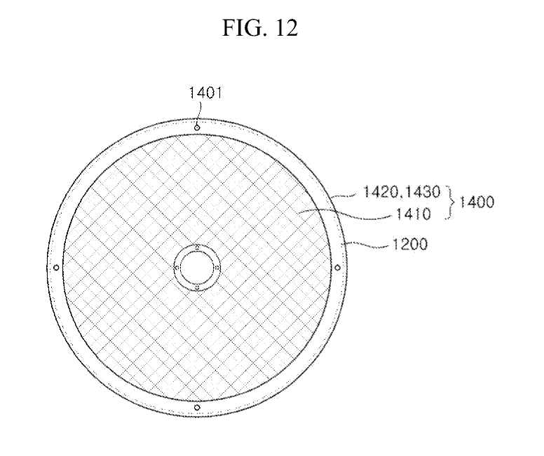

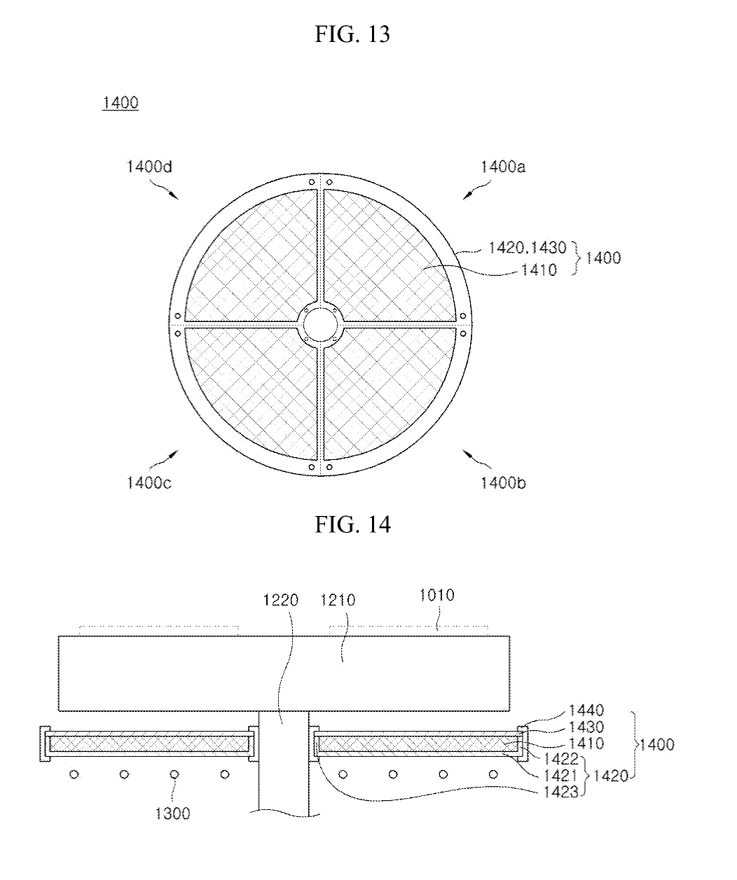

FIG. 10 illustrates a cross-sectional view of a substrate processing apparatus in accordance with a second embodiment of the present invention. FIG. 11 illustrates an exploded perspective view of a heat insulating member in accordance with the second embodiment. FIG. 12 illustrates a plan view of the heat insulating member in accordance with the second embodiment. FIG. 13 illustrates a plan view of a heat insulating member in accordance with a modification of the second embodiment. FIGS. 14 to 16 illustrate conceptual cross-sectional views for explaining shapes of the heat insulating member in accordance with modifications of the second embodiment.

Referring to FIGS. 10 to 12, the substrate processing apparatus in accordance with the second embodiment includes a chamber 1100 having an inner reaction space, a substrate seating member 1200 seating a substrate 1010 thereon in the chamber 1100, an induction heating unit 1300 heating the substrate seating member 1200 through high-frequency induction heating, and a heat insulating member 1400 disposed between the substrate seating member 1200 and the induction heating unit 1300 and collecting a heat insulator 1410 therein.

In this embodiment, the heat insulating member 1400 collecting the heat insulator 1410 therein is disposed between the substrate seating member 1200 and the induction heating unit 1300 to prevent the heat loss of the substrate seating member 1200, so that the power consumption of the induction heating unit 1300 may be reduced.

It is possible to prevent an induction coil 1310 from being contaminated by a processing gas supplied to the reaction space of the chamber 1100 by disposing the heat insulating member 1400 over the induction coil 1310 of the induction heating unit 1300.

As illustrated in FIGS. 10 to 12, the heat insulating member 1400 includes the heat insulator 1410, a lower body 1420 collecting the heat insulator 1410 therein, and an upper cover 1430 covering the lower body 1420.

The heat insulator 1410 is formed in a plate shape that has a penetration hole at its central region. The heat insulator 1410 is disposed between the induction heating unit 1300 performing the induction heating and the substrate seating member 1200 that is heated through the induction heating. Therefore, it is preferable that a diameter of the heat insulator 1410 is equal to or smaller than a diameter of a main disk 1210 of the substrate seating member 1200. In accordance with another embodiment, the diameter of the heat insulator 1410 may be greater than the diameter of the main disk 1210. However, it is effective that the diameter of the heat insulator 1410 is smaller than the diameter of the substrate seating member 1200 when considering the size of the chamber 1100 and the size of the lower body 1420 and the upper cover 1430.

The heat insulator 1410 is formed of a material having low thermal conductivity. The thermal conductivity may be less than approximately 10 W/mK. As a result, it is possible to reduce the heat loss of the substrate seating member 1200 that is heated to a high temperature.

It is preferable that a material capable of blocking radiant heat, i.e., an infrared ray, or having low transmissivity is used as the heat insulator 1410. Namely, it is possible to prevent a soleplate of the chamber 1100 or the induction heating unit 1300 from being heated by the radiant heat by blocking the radiant heat.

It is effective to form the heat insulator 1410 with a material that is not heated by an induction heating phenomenon of the induction heating unit 1300. Preferably, the heat insulator 1410 is formed of a material that does not affect a high-frequency magnetic field. As a result, it is possible not to disturb the induction heating provided to the substrate seating member 1200.

To satisfy the above properties, the heat insulator 1410 uses one or more of a heat insulator of alumina series, a heat insulator of silica series and carbon felt. The heat insulator 1410 has advantages of an excellent heat insulating function and a low price.

However, in the prior art that the heat insulator 1410 is exposed to the inside of the chamber 1100, a particle blowing phenomenon occurs by low hardness of the heat insulator 1410. Moreover, since the density of the heat insulator 1410 is low, stomas generated due to the low density contain the heat therein and thus it decreases the thermal conductivity. Since the stomas in the heat insulator 1410 contain various materials existing in the air, the contamination occurs by the outgassing of the materials. The heat insulator 1410 reacts with the byproducts or the processing gas within the chamber 1100 and thus corrosion or etching thereof occurs. As a result, the replacement of the heat insulator 1410 often occurs. However, in this embodiment, the above problems are solved by sealing the heat insulator 1410 using the lower body 1420 and the upper cover 1430. The lower body 1420 and the upper cover 1430 have thermal endurance and thus are not deformed in a high temperature. In addition, the lower body 1420 and the upper cover 1430 have chemical resistance and thus do not react with chemical substances used in fabrication processes.

As a result, it is possible to prevent the contamination due to the outgassing or the particle blowing by the heat insulator 1410 and to prevent the heat insulator 1410 from being etched or corroded, by disposing the heat insulator 1410 in an inner space of a body constructed by combining the lower body 1420 and the upper cover 1430 together.

The body formed by combining the lower body 1420 and the upper cover 1430 together completely isolates the heat insulator 1410 from its outside, i.e., the inner environment of the chamber 1100. Thus, the heat insulator 1410 is protected from the outside, and the contamination of the heat insulator 1410 as well as the contamination of the inside of the chamber 1100 due to the heat insulator 1410 may be prevented.

Herein, it is effective that the hardness of the lower body 1420 and the upper cover 1430 is greater than that of the heat insulator 1410. Thus, it is possible to protect the heat insulator 1410 from an external force. Moreover, since the lower body 1420 and the upper cover 1430 are exposed to the reaction space of the chamber 1100, it is effective that they use a material that does not react with byproducts or the processing gas.

In this embodiment, it is preferable that quartz is used as the lower body 1420 and the upper cover 1430. Ceramic may be used as the lower body 1420 and the upper cover 1430. SiC may be used as the lower body 1420 and the upper cover 1430.

As shown in FIG. 11, the lower body 1420 includes a soleplate 1421 having an axle penetration hole at its center, a first projected lateral wall 1422 protruding upwards at an edge region of the soleplate 1421, and a second projected lateral wall 1423 protruding upwards at a boundary of the penetration hole and the soleplate 1421. The heat insulator 1410 is collected in a space formed by the soleplate 1421 and the first and second projected lateral walls 1422 and 1423. Thus, as illustrated in FIG. 12, the heat insulator 1410 is formed in a band shape.

Herein, the soleplate 1421 is formed in a circular plate shape that is similar to the shape of the main disk 1210 of the substrate seating member 1200. The shape of the soleplate 1421 may be changed according to the shape of the main disk 1210.

A driving axle 1220 of the substrate seating member 1200 penetrates the axle penetration hole at the center of the soleplate 1421. Thus, the lower body 1420 can be disposed in a lower portion of the substrate seating member 1200. In addition, the movement, i.e., ascent and descent, or rotation, of the substrate seating member 1200 may not be disturbed by the heat insulating member 1400 including the lower body 1420.

Then, as shown in FIG. 11, the upper cover 1430 includes an upper plate 1431 having an axle hole at its center, a first extended lateral wall 1432 extended downwards at an edge region of the upper plate 1431, and a second extended lateral wall 1433 extended downwards at a boundary of the axle hole and the upper plate 1431. That is, in this embodiment, the upper cover 1430 and the lower body 1420 are formed to have the same shape.

As mentioned above, the heat insulator 1410 is disposed within the lower body 1420. Then, the upper cover 1430 and the lower body 1420 are combined so that the first extended lateral wall 1432 of the upper cover 1430 is attached to the first projected lateral wall 1422 of the lower body 1420 and the second extended lateral wall 1433 is attached to the second projected lateral wall 1423. Thus, the heat insulating member 1400 is formed. It is effective that the heat insulating member 1400 formed as described above is fixed onto the soleplate of the chamber 1100.

As illustrated in FIG. 12, a fixing means 1401 such as adhesives, a bolt or a screw may be used to combine the lower body 1420 and the upper cover 1430. Herein, the fixing means 1401 may be fixed to the extended lateral walls 1432 and 1433 after penetrating the projected lateral walls 1423 and 1423 from the bottom of the projected lateral walls 1423 and 1423.

The heat insulating member 1400 is not limited to the description shown above. The heat insulating member 1400 may be formed in various manners.

Hereinafter, the modifications of the heat insulating member 1400 will be described with reference to drawings. The description for the modifications to be explained below may be applied to the above-mentioned embodiments and the description for each of the modifications may be applied to other modifications.

In the modification described in FIG. 13, the heat insulating member 1400 may be formed as being divided into plural parts. For instance, as shown in FIG. 13, the heat insulating member 1400 may be formed in one circular plate shape by combining 4 numbers of heat insulating bodies 1400a, 1400b, 1400c and 1400d having a fan shape. Herein, each of the first to fourth heat insulating bodies 1400a, 1400b, 1400c and 1400d includes the heat insulator 1410, the lower body 1420 and the upper cover 1430. It is possible to enhance fabrication and processability of the heat insulating member 1400 by forming the heat insulating member 1400 with the divided plural parts. Moreover, it is possible to vary a heat insulating property of each of the plural parts by adjusting the charge amount or thickness of the heat insulator 1410 for each of the plural parts or changing a kind of the heat insulator 1410 charged into each of the plural parts. As a result, the heat insulating according to the thermal difference of the substrate seating member 1200 may be performed.

As illustrated in FIG. 14, the heat insulating member 1400 includes the lower body 1420 having a cup shape whose upper portion is opened and containing the heat insulator 1410 therein and the upper cover 1430 covering the upper portion of the lower body 1420. The heat insulating member 1400 further includes a sealing sheet 1440 attached along an adhesion plane of the lower body 1420 and the upper cover 1430.

Herein, the upper cover 1430 is formed in a plate shape and attached to the first and second projected lateral walls 1422 and 1423 of the lower body 1420. At this point, the sealing sheet 1440 is attached along a side of the adhesive plane of the upper cover 1430 and the lower body 1420. Preferably, as shown in FIG. 14, the sealing sheet 1440 is attached to an outer side of the upper cover 1430 and the first and second projected lateral walls 1422 and 1423 of the lower body 1420. Furthermore, the sealing sheet 1440 is attached to a part of a back surface of the soleplate 1421 of the lower body 1420 and a part of a top surface of the upper cover 1430.

Herein, the lower body 1420 and the upper cover 1430 can be firmly combined by the sealing sheet 1440. Moreover, it is possible to effectively prevent the outgassing or the particle blowing of the heat insulator 1410.

As illustrated in FIG. 14, the heat insulating member 1400 is connected to the driving axle 1220 of the substrate seating member 1200 and thus can move together with the substrate seating member 1200. Through this, the distance length between the heat insulating member 1400 and the substrate seating member 1200 may be maintained constantly. A plurality of substrates may be seated on the main disk 1210 of the substrate seating member 1200.

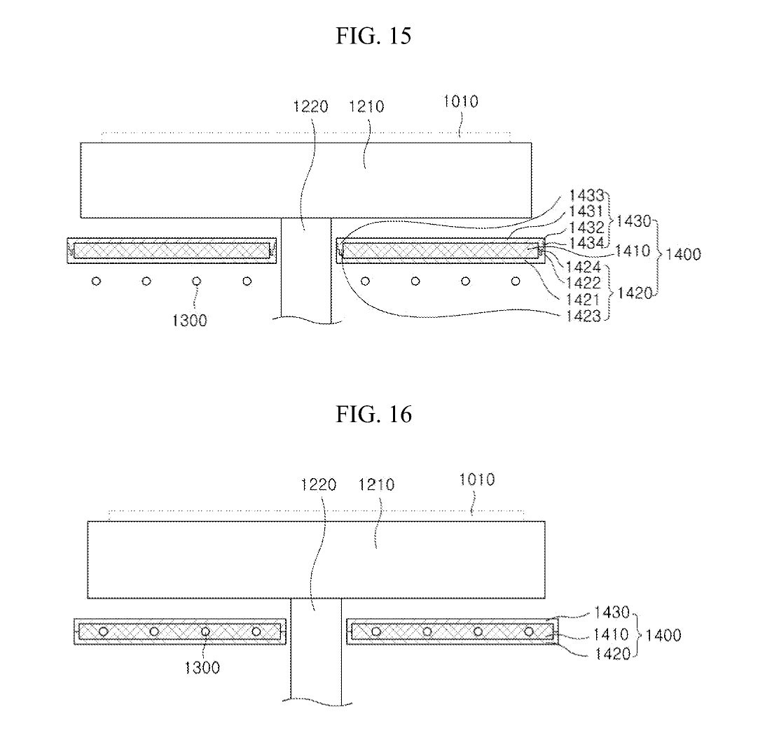

In the modification illustrated in FIG. 15, a concavo-concave pattern 1424 and 1434 may be formed on a combination plane of the lower body 1420 and the upper cover 1430 of the heat insulating member 1400. That is, as shown in FIG. 15, the concave pattern 1424 is formed at the projected lateral walls 1422 and 1423 of the lower body 1420 and the concavo pattern 1434 corresponding to the concave pattern 1424 is formed at the extended lateral walls 1432 and 1433 of the upper cover 1430. At this point, the location of the concave pattern may be changed with that of the concavo pattern or the concave pattern and the concavo pattern may be missed each other for each of the lateral walls.

Through the concavo-concave pattern formed on the combination plane, a vertical section of the combination plane of the lower body 1420 and the upper cover 1430 can be changed to a bended-line shape not a straight-line shape. As a result, it is possible to prevent the processing gas from coming into the combination plane and to prevent the outgassing and the particles run out through the combination plane.

In the modification illustrated in FIG. 16, the induction heating unit 1300 may be disposed at an inner region of the lower body 1420 of the heat insulating member 1400. That is, the induction coil 1310 of the induction heating unit 1300 may be installed in the lower body 1420 where the heat insulator 1410 is collected. This means that the induction heating unit 1300 may be disposed at an inner space of the body constructed by the lower body 1420 and the upper cover 1430 and the induction coil 1310 may be disposed within the heat insulator 1410.

Through this, the induction coil 1310 is blocked from its outer environment, i.e., the inner space of the chamber 1100, and thus the contamination of the induction coil 1310 may be prevented. At this point, it is effective that the heat insulator 1410 is disposed over the induction coil 1310. Therefore, it is possible to prevent the induction coil 1310 from being heated.

In this modification, a hole where an electric wire penetrates may be disposed at one side of the lower body 1420, wherein the electric wire electrically connects the induction coil 1310 and a high-frequency power supplying source 1320.

In addition, a plurality of heat insulators 1410 may be stacked in the heat insulating member 1400. Thus, the heat insulating effect may be further enhanced. Moreover, a plurality of heat insulating members may be stacked. The substrate processing apparatus may further include a separate case collecting and sealing the lower body 1420 and the upper cover 1430 that are combined. That is, each of the lower body 1420 and the upper cover 1430 may be formed to include two layers. At this point, the two layers may have the same or different quality. For instance, an inner layer uses ceramic and an outer layer uses quartz.

As described above, the substrate seating member 1200 is heated by the induction heating unit 1300. The substrate 1010 is also heated to a high temperature as being seated on the substrate seating member 1200 that is heated. It is possible to prevent the heat of the substrate seating member 1200 from being transmitted to the induction heating unit 1300 by disposing the heat insulating member 1400 including the heat insulator 1410 between the induction heating unit 1300 and the substrate seating member 1200. As a result, the heat loss of the substrate seating member 1200 may be prevented and the induction heating unit 1300 may be protected from the attack of the heat.

Then, a thin film is formed by injecting a processing gas through a gas injecting member 1500 onto the heated substrate 1010 in the chamber 1100. Of course, the etching may be performed by injecting the processing gas.

Hereinafter, a substrate processing apparatus in accordance with a third embodiment capable of reducing the heat loss of the substrate seating member 1200 will be described. The explanation overlapping with that of the first and second embodiments will be omitted below. Moreover, the description to be shown below can be applied to the first and second embodiments.

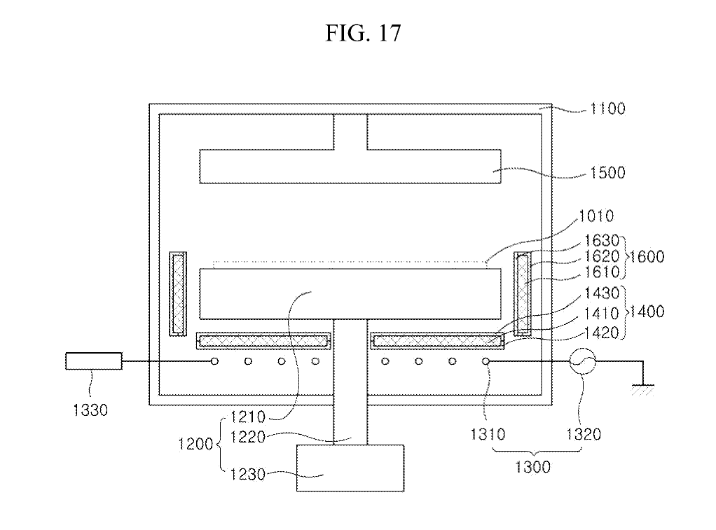

FIG. 17 illustrates a cross-sectional view of the substrate processing apparatus in accordance with the third embodiment of the present invention.

Referring to FIG. 17, the substrate processing apparatus in accordance with the third embodiment includes a chamber 1100 having an inner reaction space, a substrate seating member 1200 seating a substrate 1010 thereon in the chamber 1100, an induction heating unit 1300 heating the substrate seating member 1200 through high-frequency induction heating, a heat insulating member 1400 disposed between the substrate seating member 1200 and the induction heating unit 1300 and collecting a heat insulator 1410 therein, and a ring heat insulating member 1600 disposed between a lateral wall of the chamber 1100 and that of the substrate seating member 1200 and including a ring heat insulator 1610 therein.

The ring heat insulating member 1600 is formed in a ring shape wrapping the lateral wall of the substrate seating member 1200. It is preferable to form the ring heat insulating member 1600 in a circular ring shape. It is effective that the ring heat insulating member 1600 is formed in a shape similar to that of the heat insulating member 1400 described above. That is, the ring heat insulating member 1600 includes a lower ring body 1620 collecting the ring heat insulator 1610 and an upper ring cover 1630 covering the lower ring body 1620.

In this embodiment, it is possible to prevent the heat loss of the substrate seating member 1200 due to the lateral wall of the chamber 1100 by disposing the ring heat insulating member 1600 between the lateral wall of the substrate seating member 1200 and the lateral wall of the chamber 1100.

Hereinafter, there will be explained experimental results according to a first comparative example not using the heat insulating member 1400, a second comparative example disposing an opaque quartz window between the substrate seating member 1200 and the induction heating unit 1300, a third comparative example disposing a ceramic plate between the substrate seating member 1200 and the induction heating unit 1300, and an embodiment disposing the heat insulating member 1400 between the substrate seating member 1200 and the induction heating unit 1300. Herein, a heat insulator of alumina series was used as the heat insulator 1410 of the heat insulating member 1400. That is, the heat insulator 1410 used Al₂O₃.

Table 2 describes results of measuring power provided to the induction heating unit 1300 to heat the main disk 1210 of the substrate seating member 1200 up to a reference temperature, i.e., 800° C.

TABLE 2

| | Reference Temp. (° C.) | Power (kW) |
|---|---|---|
| 1^{st} comparative example | 800 | 66 |
| 2^{nd} comparative example | 800 | 48 |
| 3^{rd} comparative example | 800 | 38 |
| Embodiment | 800 | 23.4 |

As shown in Table 2, in case of the first comparative example not using the heat insulating member 1400, the power of 66 kW was required to heat the main disk 1210 of the substrate seating member 1200 up to 800° C. However, it is noted that, in case of disposing the heat insulating member 1400 in accordance with the embodiment, the power of 23.4 kW was only required to heat the main disk 1210 up to the same temperature, i.e., 800° C. In case of using the ceramic plate or the opaque quartz window, the power reduction was also achieved. But, in case of using the heat insulator of alumina series in accordance with the embodiment, the power consumption becomes lowest. That is, it is possible to enhance the power efficiency by using the heat insulating member 1400. This means that it is possible to heat the substrate seating member 1200 up to a desired temperature using much lower power.

Hereinafter, a substrate processing apparatus in accordance with a fourth embodiment of the present invention capable of uniformly controlling a temperature over the substrate seating member 1200 will be described. The explanation overlapping with that of the first to third embodiments will be omitted below. Moreover, the description to be shown below may be applied to the first to third embodiments.

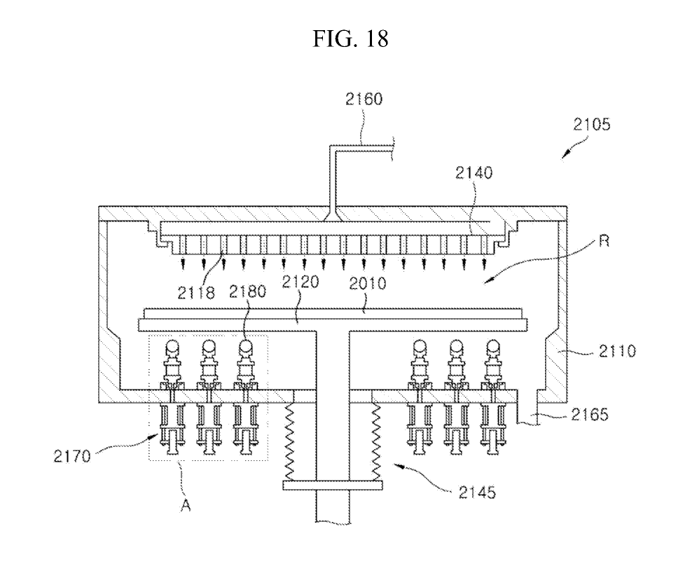

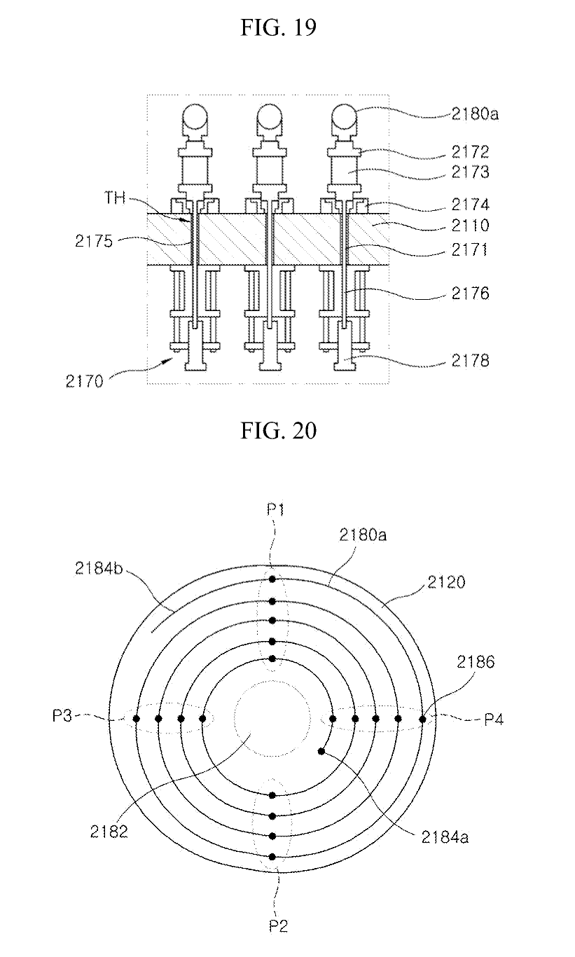

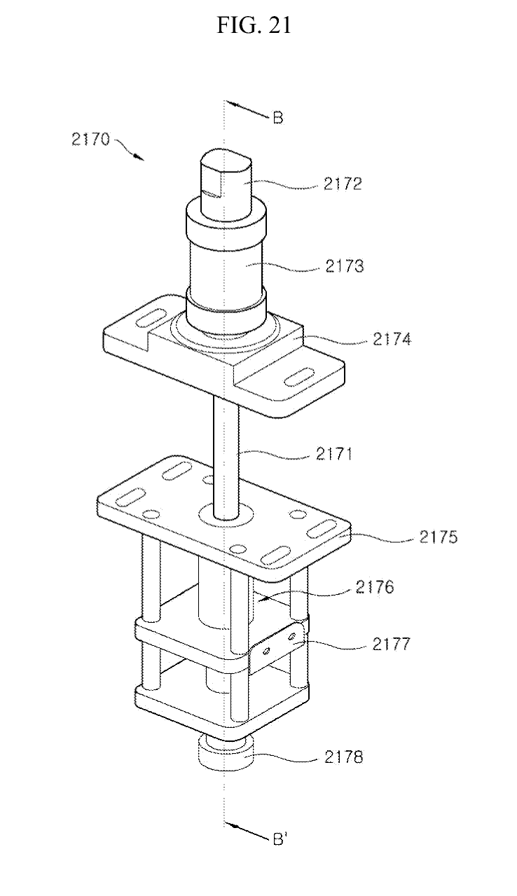

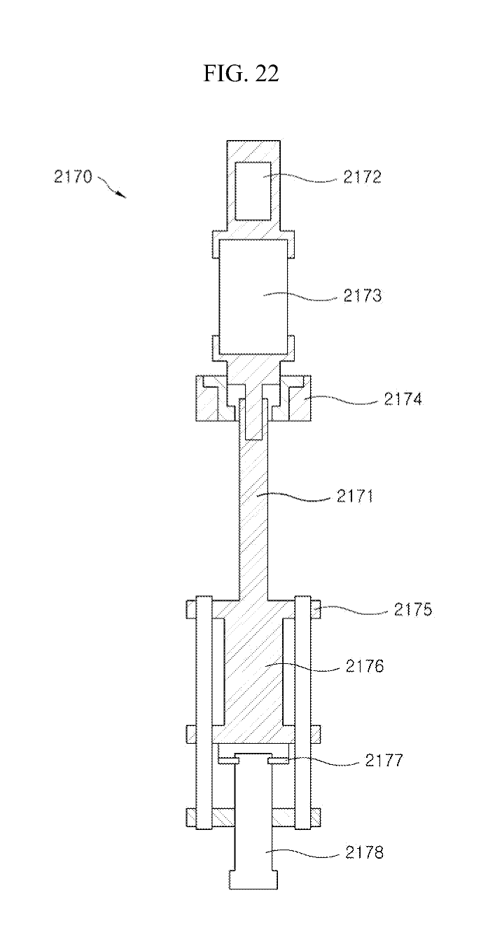

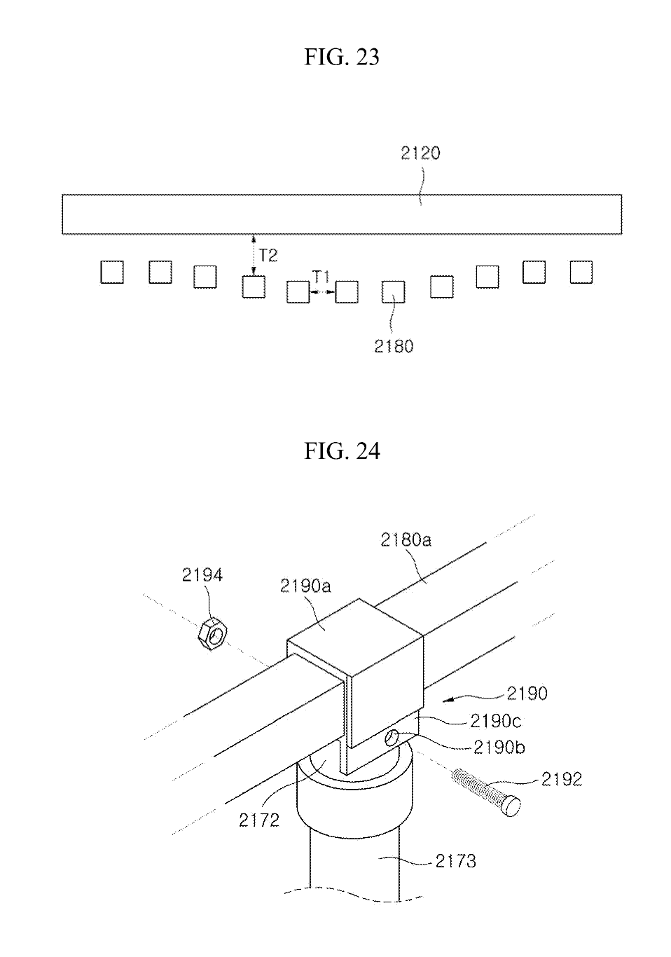

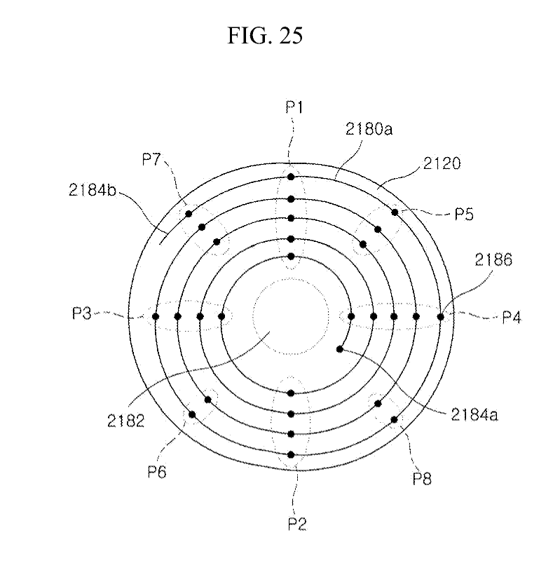

FIG. 18 illustrates a cross-sectional view of a substrate processing apparatus in accordance with a fourth embodiment of the present invention. FIG. 19 illustrates a view of an altitude adjusting unit of the induction heating scheme in accordance with the fourth embodiment and, more particularly, an enlarged view of an A region in FIG. 18. FIG. 20 illustrates a plan view of a substrate seating member in accordance with the fourth embodiment. FIG. 21 illustrates an exploded perspective view of the altitude adjusting unit in accordance with the fourth embodiment. FIG. 22 illustrates a cross-sectional view taken along a B-B′ line described in FIG. 21. FIG. 23 illustrates a cross-sectional view of a heat generating unit and the substrate seating member in accordance with the fourth embodiment. FIG. 24 illustrates a perspective view of a coil fixing device in accordance with the fourth embodiment. FIG. 25 illustrates a plane view of a heat generating unit and a substrate seating member in accordance with a modification of the fourth embodiment.

Referring to FIG. 18, the substrate processing apparatus 2105 in accordance with the fourth embodiment includes a chamber 2110 that is an essential component and thus defines a sealed reaction region R, a substrate seating member 2120 seating a substrate 2010 thereon within the chamber 2110, wherein the substrate 2010 is a processing object, a gas distribution plate 2140 over which a plurality of injection holes 2118 is formed to penetrate up and down to thereby allow a processing gas to be uniformly injected to the reaction region R, and an elevator assembly 2145 to control an elevating movement of the substrate seating member 2120.

The substrate processing apparatus 2105 further includes an induction heating unit 2180, i.e., a heat generating unit, operating in an induction heating scheme and installed under the substrate seating member 2120, and a coil, i.e., a coil having a plurality of turns, may be used as the induction heating unit 2180.

The gas distribution plate 2140 is provided with a reaction gas from a reaction gas supplying route 2160 installed to penetrate the chamber 2110. The chamber 2110 further includes an exhaust unit 2165 exhausting the reaction gas remaining in the reaction region R after being used through an external pumping system (not shown).

In this embodiment, the substrate processing apparatus 2105 further includes a plurality of altitude adjusting units 2170 penetrating a soleplate of the chamber 2110 and selectively controlling the high and low of the induction heating unit 2180, i.e., a distance between the substrate seating member 2145 and the coil.

The induction heating unit 2180 has a structural advantage that its high and low can be easily controlled without the disassembly and assembly of the chamber 2110 by the altitude adjusting units 2170 where driving motors (not shown) are built in.

Although it is not shown in detail in drawings, the induction heating unit 2180 adjusted by the altitude adjusting units 2170 moves up and down in a space under the substrate seating member 2120, so that the distance length between the substrate seating member 2120 and the induction heating unit 2180 may be adjusted. This is because the heating temperature becomes different depending on the distance length between an induction coil and a heating body during the induction heating.

Therefore, it is possible to satisfy a multi-temperature condition requiring rapid temperature variation such as 500, 600 and 700° C. by installing the altitude adjusting units 2170 at the outside of the chamber 2110, wherein the altitude adjusting units 2170 are external coil systems readily controlling the high and low of the induction heating unit 2180. At this point, the induction heating unit 2180 may be used as a means for heating the substrate 2010 seated on the substrate seating member 2120 by heating the substrate seating member 2120.

As described above, it is possible to readily adjust the high and low of the induction heating unit 2180 without the disassembly and assembly of the chamber 2110 by installing the altitude adjusting units 2170 at the outside of the chamber 2110 to control the high and low of the induction heating unit 2180.

Hereinafter, the altitude adjusting unit of the induction heating scheme in accordance with the fourth embodiment of the present invention will be described in detail with reference to accompanying drawings.

As illustrated in FIGS. 19 and 20, the substrate seating member 2120 is disposed within the chamber 2110 and the induction heating unit 2180 is disposed under the substrate seating member 2110. Furthermore, there is installed the plurality of altitude adjusting units 2170 fixing the induction heating unit 2180 and penetrating the chamber 2110 through penetration holes TH.

Herein, the induction heating unit 2180 is designed in a wound-rotor shape that its diameter is getting larger on the basis of a central axis of the substrate seating member 2120. That is, as illustrated in FIG. 25, the induction heating unit 2180 includes a coil 2180a having a plurality of turns between a starting point 2184a adjacent to a support shaft 2182 supporting the substrate seating member 2120 and an ending point 2184b adjacent to an edge region of the substrate seating member 2120, and a power supply source (not shown) providing an alternating current to the coil 2180a. The substrate seating member 2120 is indirectly heated by a magnetic field generated when supplying the current to the coil 2180a and finally the substrate 2010 is heated by the substrate seating member 2120 on which the substrate 2010 is seated.

As shown in FIG. 23, the uniformity of temperature distribution at the substrate seating member 2120 is directly affected by a first distance T1 between the turns of the coil 2180a and a second distance T2 between the coil 2180a and the substrate seating member 2120. If each of the first distance T1 and the second distance T2 is constantly maintained, a central region of the substrate seating member 2120 has a higher temperature than the edge region by the heat loss of the edge region of the substrate seating member 2120 on which the substrate 2010 is not seated. Therefore, to compensate the non-uniformity of the temperature distribution, the first distance T1 between the turns in the coil 2180a and the second distance T2 between the substrate seating member 2120 and the coil 2180a are arranged to become smaller as going from the central region to the edge region of the substrate seating member 2120. Thus, the induction heating unit 2180 is arranged in a spiral coil shape. The induction heating unit 2180 is installed in a region that is approximately 5 mm to approximately 50 mm separated from the bottom of the substrate seating member 2120. The distance between the substrate seating member 2120 and the induction heating unit 2180 is not limited to the range of approximately 5 mm to approximately 50 mm and may be set to less than 5 mm or greater than 50 mm.

As shown in FIG. 18, the plurality of altitude adjusting units 2170 is installed to measure the temperature of the substrate seating member 2120 heated by the induction heating unit 2180 and to secure the uniform temperature distribution, wherein the plurality of altitude adjusting units 2170 can be independently controlled to locally adjust the second distance T2 between the substrate seating member 2120 and the coil 2180a. The plurality of altitude adjusting units 2170 may be disposed in first, second, third and fourth setting regions P1, P2, P3 and P4 where vertical and horizontal lines passing through a center of the substrate seating member 2120 meet the coil 2180a, as shown in FIG. 20. Each of the first to fourth setting regions P1, P2, P3 and P4 includes a plurality of points 2186 where the plurality of altitude adjusting units 2170 is installed.

The second distance T2 of the substrate seating member 2120 and the coil 2180a may be locally adjusted by the plurality of altitude adjusting units 2170 connected to the coil 2180a corresponding to the plurality of points 2186. The plurality of altitude adjusting units 2170 independently operates. As illustrated in FIG. 25, the altitude adjusting unit 2170 in FIG. 21 may be further installed at the coil 2180a where a distance between the points 2186 becomes greater in a region adjacent to the edge region of the substrate seating member 2120. As shown in FIG. 25, in addition to the first to fourth setting regions P1, P2, P3 and P4 where the vertical and horizontal lines passing through the center of the substrate seating member 2120 meet the coil 2180a, the altitude adjusting units 2170 may be further installed in fifth, sixth, seventh and eighth setting regions P5, P6, P7 and P8 where two perspective lines meet each other, wherein each of the two perspective lines passes through a space between the vertical line and the horizontal line and the center of the substrate seating member 2120. Each of the fifth to eighth setting regions P5, P6, P7 and P8 includes plural points 2186 whose number is smaller than that included in each of the first to fourth setting regions P1, P2, P3 and P4.

The plurality of points 2186 where the plurality of altitude adjusting unit 2170 described in FIGS. 20 and 25 is one example and thus may be defined in various manners in regions corresponding to the coil 2180a having the plurality of turns.

Although the above description is provided on the basis of the setting regions, it is not limited thereto and the altitude can be adjusted according to the location of the induction coil of the induction heating unit 2180. That is, as described above, in case the induction coil of the induction heating unit 2180 is in a divided-line shape not in the wound-rotor shape, the altitude of each line may be different. At this point, as mentioned above, the distance length between the substrate seating member 2120 and the induction heating unit 2180 is adjusted by the altitude adjusting units 2170. Thus, it is possible to adjust a temperature of each setting region.

In this embodiment, although any one of the altitude adjusting units 2170 has defective or is damaged, only the altitude adjusting unit 2170 having the defective or being damaged can be easily repaired or replaced with a new one.

Unlike the prior art, the present invention can readily change the high and low of the induction heating unit 2180 by installing a driving motor (not shown) at the outside of the chamber 2110 without the disassembly and assembly of internal components of the chamber 2110, so that it is possible to easily control the temperature uniformity over the substrate seating member 2120.

Therefore, since there is no need to disassemble and assemble the internal components of the chamber 2110 to secure the temperature uniformity, an unnecessary time used in performing the disassembly and assembly can be reduced. Moreover, since the temperature is controlled by a bellows (not shown) at the outside of the chamber 2110, there is no fear that the inside of the chamber 2110 is contaminated and the internal components of the chamber 2110 are exposed to the outside. Thus, the longevity of the internal components of the chamber 2110 can be extended.

Specially, since it is possible to adjust the high and low of the induction heating unit 2180 for each temperature in a fabrication process by tuning the uniformity for each temperature and verifying the location even in a deposition process requiring a multi-temperature condition, the quality of a thin film may be enhanced when forming the thin film on a substrate.

Hereinafter, the altitude adjusting unit in accordance with the fourth embodiment will be described in detail.

Referring to FIGS. 21 and 22, the altitude adjusting unit 2170 includes a coil fixing support 2172 disposed at the uppermost part, an insulator 2173 wrapping a lower portion of the coil fixing support 2172, a shaft 2171 penetrating the inside of a chamber, e.g., the chamber 2110 in FIG. 19, through a penetration hole, e.g., the penetration hole TH in FIG. 19, towards a lower portion of the insulator 2173, an upper support 2174 and a lower support 2175 respectively installed at an outer side and an inner side of the chamber to maintain a vacuum state of the inside of the chamber, wherein the shaft 2171 is disposed between the upper support 2174 and the lower support 2175, a bellows 2176 disposed under the lower support 2175 to prevent the supply of an external gas and employed for an elevating movement of the shaft 2171, and a distance controller 2178 controlling the high and low of the coil fixing support 2172 and disposed under the bellows 2176.

As illustrated in FIG. 24, the coil fixing support 2172 is connected to a coil fixing device 2190 supporting the coil 2180a. The coil fixing device 2190 includes a support 2190a surrounding the coil 2180a and two arranging members 2190c extended downwards from the support 2190a and having a connection hole 2190b. The coil fixing support 2172 in FIG. 21 includes two arrangement planes 2172a respectively corresponding to the two arranging members 2190c in FIG. 24 and a fixing hole 2172b penetrating the two arrangement planes 2172a. As shown in FIG. 24, if the two arrangement members 2190c of the coil fixing device 2190 supporting the coil 2180a are aligned with the two arrangement planes 2172a, a bolt 2192 penetrates the fixing hole 2172b and the connection hole 2190b and an end of the bolt 2192 is fastened with a nut 2194.

The insulator 2173 disposed in a space between the coil fixing support 2172 and the upper support 2174 is designed to block the flow of a current between the coil fixing support 2172 and the distance controller 2178, and thus may use one of quartz and a ceramic material including AlO, AlN, BN or SiC having an excellent insulating property. The upper support 2174 and the lower support 2175 are combined with the inside and the outside of the chamber 2110 corresponding to the penetration hole TH in FIG. 19, and provide a path which the up and down movement of the shaft 2171 can be performed through the penetration hole TH.

The lower support 2175 corresponding to the penetration hole TH in FIG. 19 is connected to the bellows 2176. The bellows 2176 performs a function of sealing off the inside of the chamber 2110 from the outside when the shaft 2171 penetrates the chamber 2110 to move up and down. The distance controller 2178 is installed under the bellows 2176 and connected to the shaft 2171, thereby adjusting the altitude of the coil fixing support 2172. Since the distance controller 2178 is installed at the outside of the chamber 2110, the distance between the substrate seating member 2120 and the coil 2180a can be locally controlled without disassembling the chamber 2110. The distance controller 2178 may be operated by a driving motor (not shown).

The altitude adjusting unit 2170 further includes a sensor support 2177 installed between the bellows 2176 and the distance controller 2178, wherein a sensing device (not shown) is attached to the sensor support 2177. The sensing device attached to the sensor support 2177 plays a role of sensing the high and low of the induction heating unit. The sensing device may include a sensor or a gauge.

Herein, the induction heating unit is fixed to the coil fixing support 2172 and the high and low of the induction heating unit can vary as the shaft 2171 within the chamber moves up and down. That is, in the present invention, the high and low of the induction heating unit built into the coil fixing support 2172 can be easily controlled by moving the shaft 2171 up and down through the bellows 2176 using the distance controller 2178 installed at the outside of the chamber. Therefore, the high and low of the induction heating unit can be controlled without the disassembly and assembly of the chamber and the fabrication process is simplified.

Unlike the prior art, since the present invention does not need a tuning process for the temperature uniformity, the disassembly and assembly of the internal components of the chamber are not required. Moreover, since such a process of decline a temperature to disassemble the internal components of the chamber is omitted, the effectiveness of the equipment operation may be maximized; the inside of the chamber may not be contaminated; and the longevity of the internal components of the chamber may be extended.

In addition, since it is possible to satisfy the multi-temperature condition by installing an electric motor integrated with the distance controller 2178, the temperature uniformity is enhanced and the high and low of the induction heating unit can be precisely controlled by employing the altitude adjusting unit 2170 that is an external coil system. Moreover, since, even in a process of requiring the multi-temperature condition, it is possible to change the high and low of the induction heating unit for each temperature when performing the fabrication process by tuning the uniformity for each temperature and verifying the location, the quality of the thin film can be enhanced.

As mentioned above, the description in accordance with this embodiment may be applied to the above-explained embodiments. For instance, the altitude adjusting unit explained in the fourth embodiment may be applied to the first embodiment. That is, the altitude adjusting unit in the fourth embodiment can move the induction coil in the first embodiment up and down. Through this, it is possible to differentiate the altitude of the induction coil at a central region and an edge region. In addition, for instance, in case the induction heating unit is disposed within the heat insulating member where the heat insulator is contained as shown in the second embodiment, the altitude adjusting unit may penetrate one end of the heat insulating member to be connected to the induction coil of the induction heating unit. In this case, the induction coil moves up and down in the inner space of the heat insulating member. The present invention is not limited thereto and the altitude adjusting unit can adjust the altitude of the heat insulating member where the induction heating unit is disposed. Herein, the heat insulating member may be formed in a divided shape according to corresponding regions of the substrate seating member.

Hereinafter, a method for controlling the temperature distribution of the substrate seating member 2120 will be described with reference to FIGS. 18 to 25.

In a first step, the substrate seating member 2120 is heated up to a temperature required in the substrate processing process by supplying a current to the induction heating unit 2180 and the temperature of the substrate seating member 2120 is measured at a plurality of measuring points (not shown) and thus the measured temperature is classified into a first region and a second region, wherein the first region is higher than the temperature required in the substrate processing process and the second region is lower than the temperature required in the substrate processing process.

In a second step, the distance between the substrate seating member 2120 and the coil 2180a is widened by controlling the altitude adjusting unit 2170 corresponding to the first region and narrowed by controlling the altitude adjusting unit 2170 corresponding to the second region.

In a third step, the substrate seating member 2120 is heated up to the temperature required in the substrate processing process by supplying a current to the induction heating unit 2180 and the temperature of the substrate seating member 2120 is measured at the plurality of measuring points. Thus, if the uniform temperature distribution is secured, the substrate processing process is performed. If the first region and the second region are generated, the first and second steps are repeated.

As described above, in accordance with the present invention, it is possible to prevent the heat loss of the substrate seating member by disposing the heat insulating member between the substrate seating member and the induction heating unit.

Moreover, it is possible to heat the substrate seating member up to the high temperature with low induction heating power by preventing the heat loss of the substrate seating member, and thus to reduce the power loss of the induction heating unit.

Furthermore, it is possible to uniformly maintain the temperature distribution of the substrate seating member.

In addition, it is possible to enhance the heat insulating effect of the substrate seating member by forming the heat insulating member including the heat insulator sealed with a material such as quartz, wherein the heat insulator has an excellent heat insulating effect and low price and could not be used within the chamber.

Besides, it is possible to readily secure uniform temperature distribution of the substrate seating member without the disassembly of the processing chamber by adjusting the altitude of the induction coil disposed under the substrate seating member at the outside of the processing chamber. In particular, since the disassembly of the chamber is omitted when adjusting the distance between the substrate seating member and the coil, the disassembling and assembling time of the chamber is not necessary. Thus, the effectiveness of the equipment operation is improved. The frequency of the inside of the chamber exposed to the air is reduced and thus the longevity of the chamber can be extended.

Although the deposition apparatus has been described with reference to the specific embodiments, it is not limited thereto. Therefore, it will be readily understood by those skilled in the art that various modifications and changes can be made thereto without departing from the spirit and scope of the present invention defined by the appended claims.

What is claimed is:

1. A substrate processing apparatus, comprising:
a chamber having a reaction space therein;
a substrate seating member disposed in the reaction space of the chamber to seat a substrate thereon;
an induction heating unit to heat the substrate seating member; and
at least one altitude adjusting unit to selectively adjust the altitude of the induction heating unit at the outside of the chamber according to a temperature adjusting region of the substrate seating member.

2. The substrate processing apparatus of claim 1, wherein the altitude adjusting unit penetrates the chamber and is connected to the induction heating unit disposed under a susceptor.

3. The substrate processing apparatus of claim 1, wherein the altitude adjusting unit comprises:
a coil fixing support;
an insulator wrapping a lower portion of the coil fixing support;
a shaft penetrating the chamber towards a lower portion of the insulator;
an upper support and a lower support installed at an outer side and an inner side of the chamber, respectively, wherein the shaft is disposed between the upper support and the lower support;
a bellows to move the shaft towards a lower part of the lower support; and
a distance controller to control the movement of the coil fixing support towards a lower part of the bellows.

4. The substrate processing apparatus of claim 3, further comprising:
a plurality of driving motors corresponding to the distance controller; and
a sensor support, to which a sensing device is attached, disposed in a space between the bellows and the distance controller, wherein the sensing device uses one of a sensor and a gauge.

5. The substrate processing apparatus of claim 3, wherein the insulator comprises one of quartz and a ceramic material including AlO, AlN, BN or SiC.

6. The substrate processing apparatus of claim 1, further comprising a heat insulating member disposed between the induction heating unit and the substrate seating member, wherein the heat insulating member uses one or more of opaque quartz, SiC and ceramic.

7. The substrate processing apparatus of claim 1, further comprising a heat insulating member disposed between the induction heating unit and the substrate seating member, wherein the heat insulating member includes a heat insulator, a lower body disposed in the reaction space and collecting the heat insulator therein, and an upper cover covering the lower body, and the heat insulator uses one or more of a heat insulator of alumina series, a heat insulator of silica series and carbon felt.

8. The substrate processing apparatus of claim 1, wherein the induction heating unit is disposed within the chamber; a window member is disposed over the induction heating unit; a heat insulating member is disposed over the window member; and a plurality of supporting axles is disposed between the window member and the heat insulating member.

9. The substrate processing apparatus of claim 1, further comprising a heat insulating member disposed under the substrate seating member and collecting a heat insulator therein, the heat insulator using one or more of a heat insulator of alumina series, a heat insulator of silica series and carbon felt, wherein the induction heating unit is disposed within the heat insulating member and the altitude adjusting unit penetrates a part of the chamber to be connected to the heat insulating member.

10. The substrate processing apparatus of claim 1, wherein the induction heating unit comprises:
at least one induction coil disposed under a heat insulating member; and
a power supplying source to provide high-frequency power to the induction coil, wherein the altitude adjusting unit is connected to the induction coil.

11. A substrate processing apparatus, comprising:
a chamber having a reaction space therein;
a substrate seating member disposed in the chamber to seat a substrate thereon;
an induction heating unit to heat the substrate seating member through the induction heating;
a window member disposed over the induction heating unit; and
at least one heat insulating member disposed between the induction heating unit and the window member.

12. The substrate processing apparatus of claim 11, further comprising a plurality of supporting axles disposed between the window member and the heat insulating member.

13. The substrate processing apparatus of claim 11, wherein the heat insulating member blocks radiant heat and uses one or more of opaque quartz, SiC and ceramic that do not affect the induction heating.

14. The substrate processing apparatus of claim 11, wherein the heat insulating member includes a heat insulator, a lower body disposed in the reaction space and collecting the heat insulator therein and an upper cover covering the lower body, and the heat insulator uses one or more of a heat insulator of alumina series, a heat insulator of silica series and carbon felt.

15. The substrate processing apparatus of claim 11, further comprising an altitude adjusting unit moving the induction heating unit up and down to control a distance between the induction heating unit and the substrate seating member.

16. A substrate processing apparatus, comprising:
a chamber having a reaction space therein;
a substrate seating member disposed in the chamber to seat a substrate thereon;
a heat insulating member disposed under the substrate seating member and collecting a heat insulator therein; and
an induction heating unit disposed in the heat insulating member to heat the substrate seating member through the induction heating.

17. The substrate processing apparatus of claim 16, wherein the heat insulating member includes a lower body disposed in the reaction space and collecting the heat insulator therein and an upper cover covering the lower body, and the heat insulator uses one or more of a heat insulator of alumina series, a heat insulator of silica series and carbon felt.
